(19) United States
(12) Patent Application Publication
(10) Pub. No.: US 2025/0393137 A1
(43) Pub. Date: Dec. 25, 2025

(54) STORAGE DEVICE HEAT-MITIGATING ENCLOSURE

(71) Applicant: Sandisk Technologies, Inc., Milpitas, CA (US)

(72) Inventors: Li Chen, Sunnyvale, CA (US); Beng Gian Ooi, Penang (MY); Fu Xing Chan, Penang (MY); Ye Bai, Shanghai (CN); Kai Liu, Dublin, CA (US); Chaolun Zheng, San Jose, CA (US); Bo Yang, Dublin, CA (US); Ning Ye, San Jose, CA (US); Toshiki Hirano, San Jose, CA (US)

(21) Appl. No.: 18/747,860

(22) Filed: Jun. 19, 2024

(51) Int. Cl. H05K 5/00

(52) U.S. Cl. CPC H05K 5/0047

(57) ABSTRACT

In the context of an electronic storage device such as a solid-state drive, a heat-mitigating enclosure includes one or more thermal conduction inhibitor interposed in the respective top or bottom enclosing structure and positioned between a relatively high-temperature electronic component such as an ASIC controller and/or PMIC of a corresponding PCB and a relatively low-temperature electronic component such as NAND memory. Such a thermal conduction inhibitor may include one or more through-hole through the enclosure structure and/or a recess extending into the enclosure structure, with or without a low thermal conductivity material embedded therein.

### FIELD OF EMBODIMENTS

Embodiments of the invention may relate generally to electronic devices such as solid-state storage devices, and particularly to a heat-mitigating storage device enclosure.

### BACKGROUND

Enterprise solid-state storage devices, or solid-state drives (SSDs), are commonly used in client, hyperscale and enterprise compute environments. Since SSDs are made from flash memory (e.g., NAND (NOT AND) flash memory), they can be built in many different form factors and are typically associated with industry standard form factors and corresponding mechanical dimensions and electrical interface specifications and protocols. For example, a family of specifications referred to as Enterprise and Datacenter Standard Form Factor (EDSFF) were developed to address the concerns of data center storage. For example, EDSFF E1.L specifies a form factor designed to fit vertically in a 1 U storage system enclosure and is about three times the length of an EDSFF E1.S and supports up to 48 standard NAND sites. With the high capacity storage of the E1.L form factor, a single 1 U enclosure can store up to 32 drives. It is well-known that electronic devices generally and SSDs in particular dissipate power in the form of heat, which requires significant cooling and related costs, and can adversely affect performance, reliability, TCO (total cost of ownership), life span, and the like.

Any approaches that may be described in this section are approaches that could be pursued, but not necessarily approaches that have been previously conceived or pursued. Therefore, unless otherwise indicated, it should not be assumed that any of the approaches described in this section qualify as prior art merely by virtue of their inclusion in this section.

### BRIEF DESCRIPTION OF THE DRAWINGS

Embodiments are illustrated by way of example, and not by way of limitation, in the figures of the accompanying drawings and in which like reference numerals refer to similar elements and in which:

FIG. 1 is a block diagram illustrating a solid-state drive (SSD), according to an embodiment;

FIG. 2 is an exploded view illustrating an SSD with a heat-mitigating enclosure, according to an embodiment;

FIG. 3A is an exploded perspective view illustrating a top enclosure assembly for the SSD of FIG. 2, according to an embodiment;

FIG. 3B is an exploded perspective view illustrating a bottom enclosure assembly for the SSD of FIG. 2, according to an embodiment;

FIG. 4A is a cross-sectional view illustrating the SSD of FIG. 2, according to an embodiment;

FIG. 4B is an exploded cross-sectional view illustrating the SSD of FIG. 2, according to an embodiment;

FIG. 5A is a diagram illustrating a prior heat spreader for an SSD enclosure;

FIG. 5B is a diagram illustrating a heat-mitigating enclosure for an SSD enclosure, according to an embodiment;

FIG. 5C is a diagram illustrating the heat-mitigating enclosure of FIG. 5B with an embedded thermal splitter, according to an embodiment;

FIG. 5D is a diagram illustrating a heat-mitigating enclosure for an SSD enclosure, according to an embodiment;

FIG. 5E is a diagram illustrating a heat-mitigating enclosure for an SSD enclosure, according to an embodiment;

FIG. 5F is a diagram illustrating a heat-mitigating enclosure for an SSD enclosure, according to an embodiment; and

FIG. 6 is a flow diagram illustrating a method of assembling a data storage device, according to an embodiment.

### DETAILED DESCRIPTION

Generally, approaches to a heat-mitigating storage device enclosure, such as for solid-state drives, are described. In the following description, for the purposes of explanation, numerous specific details are set forth to provide a thorough understanding of the embodiments of the invention described herein. It will be apparent, however, that the embodiments of the invention described herein may be practiced without these specific details. In other instances, well-known structures and devices may be shown in block diagram form to avoid unnecessarily obscuring the embodiments of the invention described herein.

### INTRODUCTION

### Terminology

References herein to “an embodiment”, “one embodiment”, and the like, are intended to mean that the particular feature, structure, or characteristic being described is included in at least one embodiment of the invention. However, instances of such phrases do not necessarily all refer to the same embodiment,

The term “substantially” will be understood to describe a feature that is largely or nearly structured, configured, dimensioned, etc., but with which manufacturing tolerances and the like may in practice result in a situation in which the structure, configuration, dimension, etc. is not always or necessarily precisely as stated. For example, describing a structure as “substantially vertical” would assign that term its plain meaning, such that the sidewall is vertical for all practical purposes but may not be precisely at 90 degrees throughout.

While terms such as “optimal”, “optimize”, “minimal”, “minimize”, “maximal”, “maximize”, and the like may not have certain values associated therewith, if such terms are used herein the intent is that one of ordinary skill in the art would understand such terms to include affecting a value, parameter, metric, and the like in a beneficial direction consistent with the totality of this disclosure. For example, describing a value of something as “minimal” does not require that the value actually be equal to some theoretical minimum (e.g., zero), but should be understood in a practical sense in that a corresponding goal would be to move the value in a beneficial direction toward a theoretical minimum.

### Context

Recall that electronic devices generally and SSDs in particular dissipate power in the form of heat, which requires significant cooling and related costs and can adversely affect multiple factors during the life cycle of an SSD. Note also that generally there are two heat regions in the context of an SSD, e.g., a high temperature region and a low temperature region. The main heat spreaders associated with each region generally are the ASIC (application specific integrated circuit; generally “a controller”, for controlling operation of the device)/PMIC (power management integrated circuit, for managing/controlling power for the device) for the high temperature region and the NAND dies for the low temperature region. Thus, there is motivation for pursuing improved drive performance by reducing heat spreading effects from the relatively hot controller(s) region(s) to the relatively cool NAND region(s).

### Heat-Mitigating Storage Device Enclosure

According to an embodiment, the relatively low temperature region is isolated from the high temperature region by interrupting or intervening in the structural continuity of the enclosure structure, with or without an additional low thermal conductivity material to serve as thermal insulation.

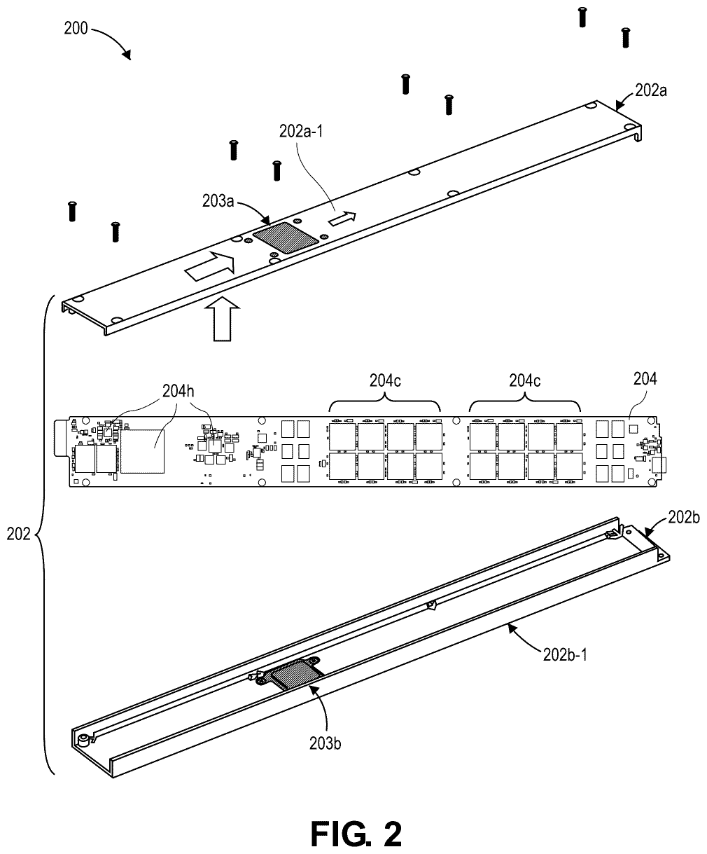

FIG. 2 is an exploded view illustrating an SSD with a heat-mitigating enclosure, according to an embodiment. Solid-state storage device 200 (or “solid-state drive” or “SSD”) comprises a printed circuit board (PCB) 204 housed in heat-mitigating enclosure 202 (or simply “enclosure 202”). Enclosure 202 comprises a first (e.g., top) enclosure part 202a comprising a first enclosing structure 202a-1 (e.g., the main structural body running the length of the device 200), and a second (e.g., bottom) enclosure part 202b coupled with the first enclosure part 202a and comprising a second enclosing structure 202b-1. According to an embodiment, at least one of the top and bottom enclosure parts 202a, 202b comprises a thermal conduction inhibitor 203a, 203b interposed in the respective top or bottom enclosing structure 202a-1, 202b-1 and positioned between a relatively high-temperature electronic component 204h (“h” for hot) of the PCB 204 and a relatively low-temperature electronic component 204c (“c” for cool) of the PCB 204. The one or more thermal conduction inhibitor 203a, 203b is positioned between the relatively high and low temperature components 204h, 204c or regions of PCB 204 to mitigate, inhibit the heat spreading effect from the hotter high-temperature component(s) 204h to the cooler low-temperature component(s) 204c via thermal conduction within the respective first and second enclosing structure 202a-1, 202b-1. According to an embodiment, each of the first and second enclosure parts 202a, 202b comprises a respective thermal conduction inhibitor 203a, 203b (as depicted in FIG. 2 et seq.).

For example and according to an embodiment, the relatively high-temperature electronic component(s) 204h of PCB 204 is or includes a controller integrated circuit component (e.g., an SSD ASIC (application-specific integrated circuit) controller) and/or a power management integrated circuit component (PMIC), and the relatively low-temperature electronic component(s) 204c is or includes one or more solid-state memory component, such as NAND memory dies. Consequently, in this context the NAND temperature is expected to decrease while the ASIC temperature is expected to increase because of reduced heat conduction through the enclosure 202a, 202b. Thus, drive performance enhancement is expected due to a reduced heat regime for the NAND memory.

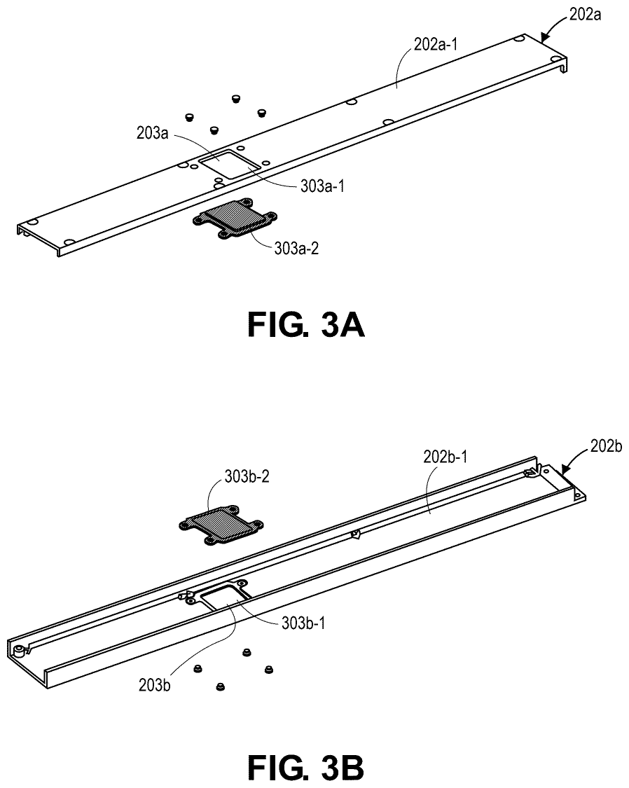

FIG. 3A is an exploded perspective view illustrating a top enclosure assembly for the SSD of FIG. 2, and FIG. 3B is an exploded perspective view illustrating a bottom enclosure assembly for the SSD of FIG. 2, both according to embodiments. According to an embodiment, the thermal conduction inhibitor 203a (FIGS. 2, 3A) comprises a through-hole 303a-1 through the first enclosing structure 202a-1 of the first enclosure part 202a, and/or the thermal conduction inhibitor 203b (FIGS. 2, 3B) comprises a through-hole 303b-1 through the second enclosing structure 202b-1 of the second enclosure part 202b. According to a related embodiment, a low thermal conductivity material 303a-2, 303b-2 (e.g., a “thermal splitter”) is disposed within one or both respective through-hole 303a-1, 303b-1, where the thermal conductivity of the low thermal conductivity material 303a-2, 303b-2 is less than the thermal conductivity of the material of which the respective first and second enclosing structure 202a-1, 202b-1 is composed. For example, each enclosing structure 202a-1, 202b-1 may be composed of aluminum (e.g., an aluminum alloy) while the low thermal conductivity material 303a-2, 303b-2 embedded within the corresponding through-hole 303a-1, 303b-1 (e.g., coupled to the enclosing structure 202a-1, 202b-1 with a set of fasteners) is composed of a plastic or a stainless steel. Such an embodiment further thermally isolates/insulates the relatively high-temperature ASIC controller and PMICs for example, i.e., the high power and high temperature tolerance components, from NAND packages that have a significantly lower temperature limit. Note that temperature margin (e.g., operating temperature limit minus “measured” junction temperature) of each type of electronic component is of interest in the context of optimizing respective component temperatures. While the ASIC controller, for example, consumes more power and therefore typically runs hotter than the NAND, the ASIC also has a higher temperature limit and thus has been identified as having a higher thermal margin (e.g., less thermal risk). Compared with a conventional one piece enclosure design, simulation has shown that an enclosure as described may provide approximately 1.4° C. extra thermal margin to the NAND packages which are generally known to be negatively impacted by excessive heat and thus more thermally challenged to meet design specifications.

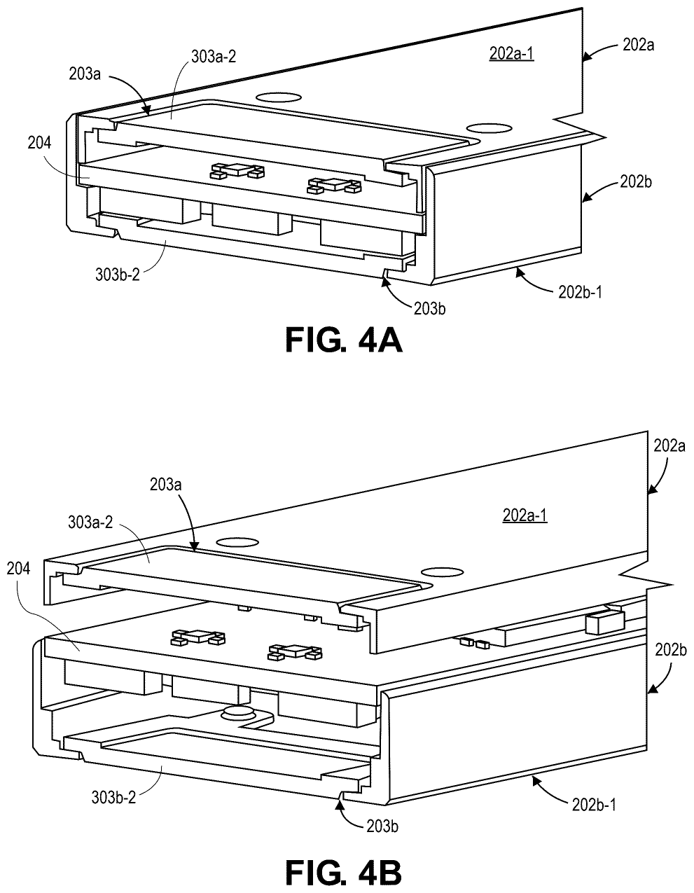

FIG. 4A is a cross-sectional view illustrating the SSD of FIG. 2, and FIG. 4B is an exploded cross-sectional view illustrating the SSD of FIG. 2, both according to embodiments. FIGS. 4A-4B provide additional illustration of the embedded “thermal splitter” components, e.g., the low thermal conductivity material 303a-2, 303b-2. As described in reference to FIGS. 3A-3B, according to an embodiment the thermal conduction inhibitor 203a (e.g., see also FIGS. 2, 3A) may comprise a through-hole 303a-1 (FIG. 3A) through the first enclosing structure 202a-1 of the first enclosure part 202a, with a corresponding low thermal conductivity material 303a-2 disposed therein. Likewise, according to an embodiment the thermal conduction inhibitor 203b (e.g., see also FIGS. 2, 3B) may comprise a through-hole 303b-1 (FIG. 3B) through the second enclosing structure 202b-1 of the second enclosure part 202b, with a corresponding low thermal conductivity material 303b-2 disposed therein.

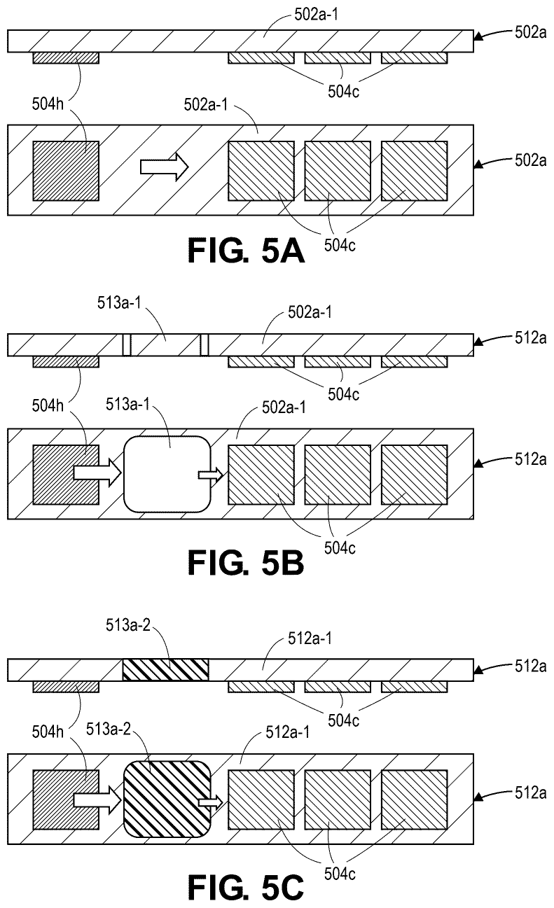

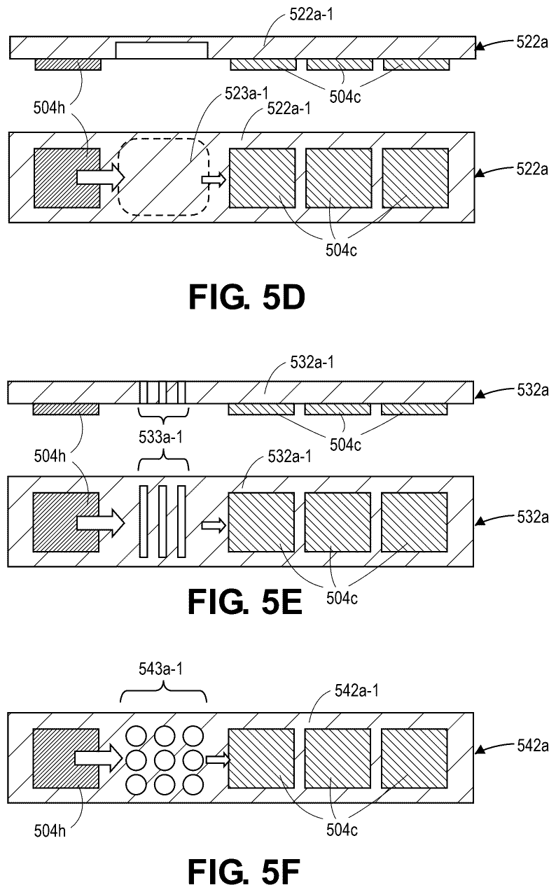

FIG. 5A is a diagram illustrating a prior heat spreader for an SSD enclosure. A side view (upper image) and a plan view (lower image) of a top enclosing structure 502a-1 of an enclosing part 502a depicts a prior heat spreader approach to limiting the amount of heat that may conduct through the enclosing structure 502a-1 from a relatively high-temperature electronic component 504h (e.g., an ASIC) to a relatively low-temperature electronic component 504c (e.g., a group of NAND dies). The approach depicted here relies on a simple gap between the positioning of the relatively high-temperature electronic component 504h and the relatively low-temperature electronic component 504c of a corresponding PCB (e.g., only a simplified version of PCB electronic components depicted here and subsequently for general positional context, and not drawn to scale).

FIG. 5B is a diagram illustrating a heat-mitigating enclosure for an SSD enclosure, according to an embodiment. A cross-sectional side view (upper image) and a plan view (lower image) of a top enclosing structure 512a-1 of an enclosing part 512a depicts a thermal conduction inhibitor approach to limiting the amount of heat that may conduct through the enclosing structure 512a-1 from a relatively high-temperature electronic component 504h (e.g., an ASIC) to a relatively low-temperature electronic component 504c (e.g., a group of NAND dies). The embodiment depicted here relies on a through-hole 513a-1 between the positioning of the relatively high-temperature electronic component 504h and the relatively low-temperature electronic component 504c of a corresponding PCB, with the block arrows (not intended to be to scale thermally) generally depicting the diminishment of thermal conduction from the “hot” region (e.g., ASIC 504h position) to the “cool” region (e.g., NAND 504c position). Note that the precise size and shape of the through-hole 513a-1 may vary from implementation to implementation, as long as such a thermal conduction inhibitor is positioned largely between the hot and cool components/regions.

FIG. 5C is a diagram illustrating the heat-mitigating enclosure of FIG. 5B with an embedded thermal splitter, according to an embodiment. A cross-sectional side view (upper image) and a plan view (lower image) of the top enclosing structure 512a-1 of the enclosing part 512a depicts a thermal conduction inhibitor approach to limiting the amount of heat that may conduct through the enclosing structure 512a-1 from a relatively high-temperature electronic component 504h (e.g., an ASIC) to a relatively low-temperature electronic component 504c (e.g., a group of NAND dies). The embodiment depicted here relies on a through-hole 513a-1 (see, e.g., FIG. 5B), and a corresponding low thermal conductivity material 513a-2 disposed therein, between the positioning of the relatively high-temperature electronic component 504h and the relatively low-temperature electronic component 504c of a corresponding PCB, with the block arrows (not intended to be to scale thermally) generally depicting the diminishment of thermal conduction from the “hot” region to the “cool” region.

FIG. 5D is a diagram illustrating a heat-mitigating enclosure for an SSD enclosure, according to an embodiment. A cross-sectional side view (upper image) and a plan view (lower image) of a top enclosing structure 522a-1 of an enclosing part 522a depicts a thermal conduction inhibitor approach to limiting the amount of heat that may conduct through the enclosing structure 522a-1 from a relatively high-temperature electronic component 504h (e.g., an ASIC) to a relatively low-temperature electronic component 504c (e.g., a group of NAND dies). The embodiment depicted here relies on a recessed portion 523a-1 extending through a portion of the enclosing structure 522a-1 between the positioning of the relatively high-temperature electronic component 504h and the relatively low-temperature electronic component 504c of a corresponding PCB, with the block arrows (not intended to be to scale thermally) generally depicting the diminishment of thermal conduction from the “hot” region (e.g., ASIC 504h position) to the “cool” region (e.g., NAND 504c position). As with the embodiment illustrated and described in reference to FIG. 5C, here too according to an embodiment a corresponding low thermal conductivity material such as 513a-2 (FIG. 5C) may be disposed within the recessed portion 523a-1 of enclosing structure 522a-1. Note that the precise size and shape of the recessed portion 523a-1 may vary from implementation to implementation, as long as such a thermal conduction inhibitor is positioned largely between the hot and cool components/regions.

FIG. 5E is a diagram illustrating a heat-mitigating enclosure for an SSD enclosure, according to an embodiment. A cross-sectional side view (upper image) and a top view (lower image) of a top enclosing structure 532a-1 of an enclosing part 532a depicts a thermal conduction inhibitor approach to limiting the amount of heat that may conduct through the enclosing structure 532a-1 from a relatively high-temperature electronic component 504h (e.g., an ASIC) to a relatively low-temperature electronic component 504c (e.g., a group of NAND dies). The embodiment depicted here relies on a grouping of slits 533a-1 through the enclosing structure 532a-1 between the positioning of the relatively high-temperature electronic component 504h and the relatively low-temperature electronic component 504c of a corresponding PCB, with the block arrows (not intended to be to scale thermally) generally depicting the diminishment of thermal conduction from the “hot” region (e.g., ASIC 504h position) to the “cool” region (e.g., NAND 504c position). Note that the precise size, shape, orientation, number, configuration of the grouping of slits 533a-1 may vary from implementation to implementation, as long as such a thermal conduction inhibitor is positioned largely between the hot and cool components/regions. For a non-limiting example, the grouping of slits 533a-1 may be oriented at an angle to the outer edges rather than extending normal to the outer edges as depicted in FIG. 5E.

FIG. 5F is a diagram illustrating a heat-mitigating enclosure for an SSD enclosure, according to an embodiment. A cross-sectional side view (upper image) of a top enclosing structure 542a-1 of an enclosing part 542a depicts a thermal conduction inhibitor approach to limiting the amount of heat that may conduct through the enclosing structure 542a-1 from a relatively high-temperature electronic component 504h (e.g., an ASIC) to a relatively low-temperature electronic component 504c (e.g., a group of NAND dies). The embodiment depicted here relies on a grouping (e.g., an array) of holes 543a-1 through the enclosing structure 542a-1 between the positioning of the relatively high-temperature electronic component 504h and the relatively low-temperature electronic component 504c of a corresponding PCB, with the block arrows (not intended to be to scale thermally) generally depicting the diminishment of thermal conduction from the “hot” region (e.g., ASIC 504h position) to the “cool” region (e.g., NAND 504c position). Note that the precise size, shape, number, configuration of the grouping of holes 543a-1 may vary from implementation to implementation, as long as such a thermal conduction inhibitor is positioned largely between the hot and cool components/regions.

### Method of Assembling a Data Storage Device

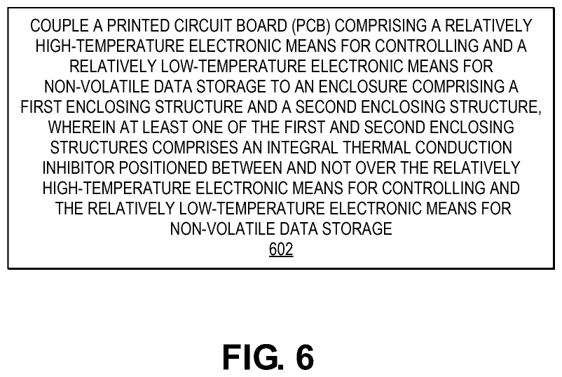

FIG. 6 is a flow diagram illustrating a method of assembling a data storage device, according to an embodiment. For example, the method of FIG. 6 may be implemented to assemble a (e.g., solid-state) storage device such as storage device 200 (FIG. 2) as exemplified in the illustrations and descriptions corresponding to FIGS. 2-5F.

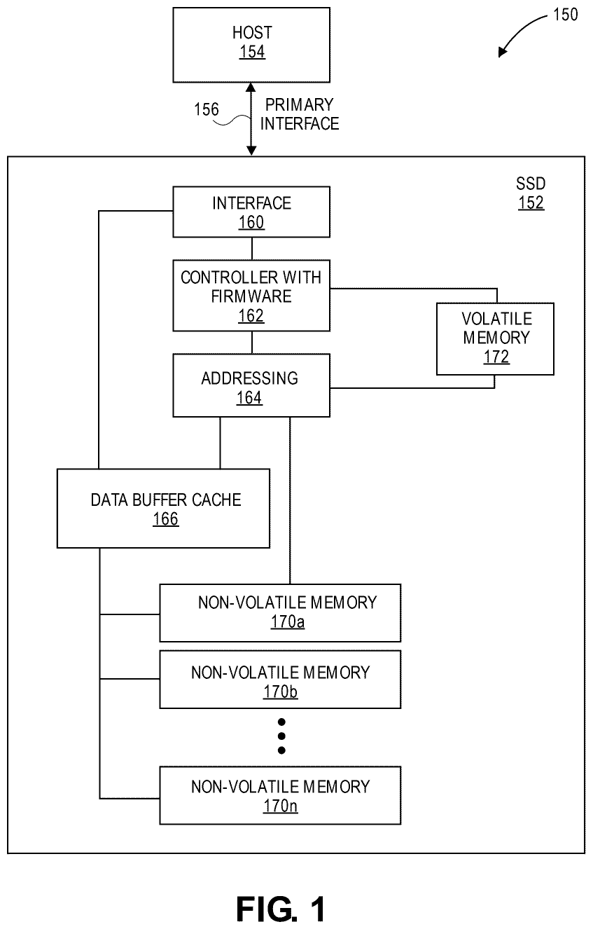

At block 602, couple a printed circuit board (PCB) comprising a relatively high-temperature electronic means for controlling and a relatively low-temperature electronic means for non-volatile data storage to an enclosure comprising a first enclosing structure and a second enclosing structure, where at least one of the first and second enclosing structures comprises an integral thermal conduction inhibitor positioned between and not over the relatively high-temperature electronic means for controlling and the relatively low-temperature electronic means for non-volatile data storage. For example, PCB 204 (FIGS. 2, 4A-4B) comprising a relatively high-temperature electronic means for controlling (e.g., relatively high-temperature electronic component 204h of FIG. 2, 504h of FIGS. 5B-5F) and a relatively low-temperature electronic means for non-volatile data storage (e.g., relatively low-temperature electronic component 204c of FIG. 2, 504c of FIGS. 5B-5F) is coupled to an enclosure part 202a, 202b (FIGS. 2-4B), 512a (FIGS. 5B-5C), 522a (FIG. 5D), 532a (FIG. 5E), 542a (FIG. 5F) comprising a first (e.g., top) enclosing structure 202a-1 (FIGS. 2-4B), 512a-1 (FIGS. 5B-5C), 522a-1 (FIG. 5D), 532a-1 (FIG. 5E), 542a-1 (FIG. 5F) and a second (e.g., bottom) enclosing structure 202b-1 (FIGS. 2-4B), where at least one of the first and second enclosing structures comprises an integral thermal conduction inhibitor part 203a, 203b (FIGS. 2-4B), 513a-1 and 513a-2 (FIGS. 5B-5C), 523a-1 (FIG. 5D), 533a-1 (FIG. 5E), 543a-1 (FIG. 5F) positioned between the relatively high-temperature electronic means for controlling and the relatively low-temperature electronic means for non-volatile data storage.

Thus, for a storage device such as an SSD, implementation of one or more thermal conduction inhibitor features described herein enables mitigation and dissipation of the conduction of heat through the corresponding metal enclosure structure itself, such as from a hotter region (e.g., location of ASIC controller and/or PMIC) of the corresponding PCB to a cooler region (e.g., location of NAND memory) of the PCB, between which the thermal conduction inhibitor(s) is positioned. This arrangement can improve drive performance by reducing heat spreading effects from the relatively hot controller(s) region(s) to the relatively cool NAND region(s), thereby diminishing NAND temperature/margin, as the low temperature region is isolated from the high temperature region by interrupting or intervening in the structural continuity of the enclosure structure.

### Physical Description of an Illustrative Operating Context

Embodiments may be used in the context of electronic devices including digital data storage devices (DSDs), such as a solid-state drives (SSDs). Thus, FIG. 1 is a block diagram illustrating a generic SSD architecture 150, for an example operating context of an electronic device with which embodiments of the invention may be implemented. The generic SSD architecture 150 depicts an SSD 152 communicatively coupled with a host 154 through a primary communication interface 156. SSD implementations are not limited to a configuration as depicted in FIG. 1, as embodiments may be implemented with SSD configurations other than that illustrated in FIG. 1 and/or with electronic devices other than SSDs.

Host 154 broadly represents any type of computing hardware, software, or firmware (or any combination of the foregoing) that makes, among others, data I/O requests or calls to one or more memory device. For example, host 154 may be an operating system executing on a computer, a tablet, a mobile phone, or generally any type of computing device that contains or interacts with storage memory. The primary interface 156 coupling host 154 to SSD 152 may be, for example, a storage system's internal bus or a communication cable or a wireless communication link, or the like.

The example SSD 152 illustrated in FIG. 1 includes an interface 160, a controller 162 (e.g., a controller having firmware logic therein), an addressing 164 function block, data buffer cache 166, and one or more non-volatile memory (NVM) components 170a, 170b-170n, where n represents an arbitrary number of NVM components that may vary from implementation to implementation.

Interface 160 is a point of interaction between components, namely SSD 152 and host 154 in this context, and is applicable at the level of both hardware and software. This enables a component to communicate with other components via an input/output (IO) system and an associated protocol. A hardware interface is typically described by the mechanical, electrical and logical signals at the interface and the protocol for sequencing them. Some non-limiting examples of common and standard interfaces include SCSI (Small Computer System Interface), SAS (Serial Attached SCSI), and SATA (Serial ATA).

An SSD 152 includes a controller 162, which incorporates the electronics that bridge the non-volatile memory components (e.g., NAND flash) to the host, such as non-volatile memory 170a, 170b-170n to host 154. The controller is typically an embedded processor that executes firmware-level code and can be a significant factor in SSD performance.

Controller 162 interfaces with non-volatile memory 170a, 170b-170n via an addressing 164 function block. The addressing 164 function operates, for example, to manage mappings between logical block addresses (LBAs) from the host 154 to a corresponding physical block address on the SSD 152, namely, on the non-volatile memory 170a, 170b-170n of SSD 152. Because the non-volatile memory page and the host sectors are different sizes, an SSD has to build and maintain a data structure that enables it to translate between the host writing data to or reading data from a sector, and the physical non-volatile memory page on which that data is actually placed. This table structure or “mapping” may be built and maintained for a session in the SSD's volatile memory 172, such as DRAM or some other local volatile memory component accessible to controller 162 and addressing 164. Alternatively, the table structure may be maintained more persistently across sessions in the SSD's non-volatile memory such as non-volatile memory 170a, 170b-170n.

Addressing 164 interacts with data buffer cache 166, in addition to non-volatile memory 170a, 170b-170n. Data buffer cache 166 of an SSD 152 typically uses DRAM as a cache, similar to the cache in hard disk drives. Data buffer cache 166 serves as a buffer or staging area for the transmission of data to and from the non-volatile memory components, as well as serves as a cache for speeding up future requests for the cached data. Data buffer cache 166 is typically implemented with volatile memory so the data stored therein is not permanently stored in the cache, i.e., the data is not persistent.

Finally, SSD 152 includes the one or more non-volatile memory 170a, 170b-170n components. For a non-limiting example, the non-volatile memory components 170a, 170b-170n may be implemented as flash memory (e.g., NAND or NOR flash), or other types of solid-state memory available now or in the future. The non-volatile memory 170a, 170b-170n components are the actual memory electronic components on which data is persistently stored. The non-volatile memory 170a, 170b-170n components of SSD 152 can be considered the analogue to the hard disks in hard-disk drive (HDD) storage devices.

Furthermore, references herein to a data storage device may encompass a multi-medium storage device (or “multi-medium device”, which may at times be referred to as a “multi-tier device” or “hybrid drive”). A multi-medium storage device refers generally to a storage device having functionality of both a traditional HDD (see, e.g., HDD 100) combined with an SSD (see, e.g., SSD 150) using non-volatile memory, such as flash or other solid-state (e.g., integrated circuits) memory, which is electrically erasable and programmable. As operation, management and control of the different types of storage media typically differ, the solid-state portion of a hybrid drive may include its own corresponding controller functionality, which may be integrated into a single controller along with the HDD functionality. A multi-medium storage device may be architected and configured to operate and to utilize the solid-state portion in a number of ways, such as, for non-limiting examples, by using the solid-state memory as cache memory, for storing frequently-accessed data, for storing I/O intensive data, for storing metadata corresponding to payload data (e.g., for assisting with decoding the payload data), and the like. Further, a multi-medium storage device may be architected and configured essentially as two storage devices in a single enclosure, i.e., a traditional HDD and an SSD, with either one or multiple interfaces for host connection.

### Extensions and Alternatives

In the foregoing description, embodiments of the invention have been described with reference to numerous specific details that may vary from implementation to implementation. Therefore, various modifications and changes may be made thereto without departing from the broader spirit and scope of the embodiments. Thus, the sole and exclusive indicator of what is the invention, and is intended by the applicants to be the invention, is the set of claims that issue from this application, in the specific form in which such claims issue, including any subsequent correction. Any definitions expressly set forth herein for terms contained in such claims shall govern the meaning of such terms as used in the claims. Hence, no limitation, element, property, feature, advantage or attribute that is not expressly recited in a claim should limit the scope of such claim in any way. The specification and drawings are, accordingly, to be regarded in an illustrative rather than a restrictive sense.

In addition, in this description certain process steps may be set forth in a particular order, and alphabetic and alphanumeric labels may be used to identify certain steps. Unless specifically stated in the description, embodiments are not necessarily limited to any particular order of carrying out such steps. In particular, the labels are used merely for convenient identification of steps, and are not intended to specify or require a particular order of carrying out such steps.

What is claimed is:

1. An electronic storage device comprising:
an enclosure comprising:
a top enclosure part comprising a top enclosing structure, and
a bottom enclosure part coupled with the top enclosure part and comprising a bottom enclosing structure; and
a printed circuit board (PCB) housed in the enclosure;
wherein at least one of the top and bottom enclosure parts comprises a thermal conduction inhibitor interposed in the respective top or bottom enclosing structure and positioned between a relatively high-temperature electronic component of the PCB and a relatively low-temperature electronic component of the PCB.

2. The electronic storage device of claim 1, wherein each of the top and bottom enclosure parts comprises a respective thermal conduction inhibitor.

3. The electronic storage device of claim 1, wherein:
the relatively high-temperature electronic component includes a controller integrated circuit component; and
the relatively low-temperature electronic component includes of one or more solid-state memory component.

4. The electronic storage device of claim 1, wherein:
the relatively high-temperature electronic component includes of a power management integrated circuit component; and
the relatively low-temperature electronic component includes of one or more solid-state memory component.

5. The electronic storage device of claim 1, wherein the thermal conduction inhibitor comprises a through-hole through the respective top or bottom enclosing structure of the at least one top and bottom enclosure parts.

6. The electronic storage device of claim 5, further comprising:
a low thermal conductivity material disposed within the through-hole;
wherein the thermal conductivity of the low thermal conductivity material is less than the thermal conductivity of a material of which the respective top and bottom enclosing structure is composed.

7. The electronic storage device of claim 1, wherein the thermal conduction inhibitor comprises a recessed portion extending through a portion of the respective top or bottom enclosing structure of the at least one top and bottom enclosure parts.

8. The electronic storage device of claim 7, further comprising:
a low thermal conductivity material embedded within the recessed portion;
wherein the thermal conductivity of the low thermal conductivity material is less than the thermal conductivity of a material of which the respective top and bottom enclosing structure is composed.

9. The electronic storage device of claim 1, wherein the thermal conduction inhibitor comprises a grouping of slits through the respective top or bottom enclosing structure of the at least one top and bottom enclosure parts.

10. The electronic storage device of claim 1, wherein the thermal conduction inhibitor comprises a grouping of holes through the respective top or bottom enclosing structure of the at least one top and bottom enclosure parts.

11. The electronic storage device of claim 1, wherein the electronic storage device is a solid-state drive (SSD) storage device.

12. A solid-state storage device enclosure in which a printed circuit board (PCB) comprising electronic means for non-volatile data storage is housed, the enclosure comprising:
a first enclosure part comprising a first enclosing structure; and
a second enclosure part coupled with the first enclosure part and comprising a second enclosing structure;
wherein at least one of the first and second enclosure parts comprises a thermal conduction inhibitor integral to the respective first or second enclosing structure and positioned for interposition between a relatively high-temperature electronic component of the PCB and a relatively low-temperature electronic component of the PCB.

13. The enclosure of claim 12, wherein each of the first and second enclosure parts comprises a respective thermal conduction inhibitor.

14. The enclosure of claim 12, wherein the thermal conduction inhibitor comprises a through-hole through, and/or a recessed portion extending through a portion of, the respective top or bottom enclosing structure of the at least one top and bottom enclosure parts.

15. The enclosure of claim 14, further comprising:
a low thermal conductivity material disposed within the through-hole and/or recessed portion;
wherein the thermal conductivity of the low thermal conductivity material is less than the thermal conductivity of a material of which the respective top and bottom enclosing structure is composed.

16. The enclosure of claim 12, wherein the low thermal conductivity material is composed of a plastic or a stainless steel.

17. The enclosure of claim 12, wherein the thermal conduction inhibitor comprises a grouping of slits through the respective top or bottom enclosing structure of the at least one top and bottom enclosure parts.

18. The enclosure of claim 12, wherein the thermal conduction inhibitor comprises a grouping of holes through the respective top or bottom enclosing structure of the at least one top and bottom enclosure parts.

19. A method of assembling solid-state data storage device, the method comprising:
coupling a printed circuit board (PCB) comprising a relatively high-temperature electronic means for controlling and a relatively low-temperature electronic means for non-volatile data storage to an enclosure comprising a first enclosing structure and a second enclosing structure;
wherein at least one of the first and second enclosing structures comprises an integral thermal conduction inhibitor positioned between and not over the relatively high-temperature electronic means for controlling and the relatively low-temperature electronic means for non-volatile data storage.

20. The method of claim 19, wherein coupling the PCB to the enclosure includes coupling the PCB to each of the first and second enclosure structures comprising:
a respective through-hole through, and/or a recessed portion extending through a portion of, the respective first and second enclosing structure, and
a low thermal conductivity material disposed within the through-hole and/or recessed portion, wherein the thermal conductivity of the low thermal conductivity material is less than the thermal conductivity of a material of which the respective first and second enclosing structure is composed.
